(19) United States
(12) Patent Application Publication
(10) Pub. No.: US 2025/0070529 A1
(43) Pub. Date: Feb. 27, 2025

(54) LASER MODULE

(71) Applicant: TDK CORPORATION, Tokyo (JP)

(72) Inventors: Shigeaki TANAKA, Tokyo (JP); Takashi Aoyagi, Tokyo (JP); Tsuyoshi Komaki, Tokyo (JP)

(73) Assignee: TDK CORPORATION, Tokyo (JP)

(21) Appl. No.: 18/774,986

(22) Filed: Jul. 17, 2024

(30) Foreign Application Priority Data
Aug. 22, 2023 (JP) 2023-134530

(51) Int. Cl. H01S 5/02315; H01S 5/026

(52) U.S. Cl. CPC H01S 5/02315; H01S 5/0264

(57) ABSTRACT

A laser module includes: a first laser element having a first emission port that emits first laser light; and a second laser element having a second emission port that emits second laser light. The first laser element and the second laser element are disposed such that the first laser light and the second laser light overlap each other.

### CROSS-REFERENCE TO RELATED APPLICATION

This application claims the benefit of priority to Japanese Patent Application No. 2023-134530 filed with the Japan Patent Office on Aug. 22, 2023, the entire contents of which are hereby incorporated by reference.

### TECHNICAL FIELD

The present disclosure relates to a laser module.

### BACKGROUND

There is known a laser module which multiplexes laser lights output from a plurality of laser diodes and outputs the multiplexed laser light. For example, JP 2016-133746 A describes a laser module including a red laser diode, a green laser diode, a blue laser diode, and a dichroic mirror corresponding to each laser diode.

### SUMMARY

In the laser module described in JP 2016-133746 A, dichroic mirrors are provided for multiplexing the laser lights output from the laser diodes. Therefore, there is a possibility that the size of the laser module is increased.

The present disclosure describes a laser module that can be miniaturized.

A laser module according to one aspect of the present disclosure includes: a first laser element having a first emission port that emits first laser light; and a second laser element having a second emission port that emits second laser light. The first laser element and the second laser element are disposed such that the first laser light and the second laser light overlap each other.

In the laser module, the first laser element and the second laser element are disposed so that the first laser light and the second laser light overlap each other. Therefore, the first laser light and the second laser light can be multiplexed without using any optical component such as a dichroic mirror. As a result, the laser module can be miniaturized.

The above-described laser module may further include a substrate having a mounting surface on which the first laser element is mounted. A distance from the mounting surface to the first emission port may be different from a distance from the mounting surface to the second emission port. In this case, even if the first emission port and the second emission port are close to each other, the possibility that the laser light emitted from one laser element is blocked by the other laser element is reduced. Therefore, the angle between the emission direction of the first laser light and the emission direction of the second laser light can be made small. This makes it possible to suppress the degree of divergence of the first laser light and the second laser light downstream in the emission direction from the position where the first laser light and the second laser light overlap.

The above-described laser module may further include a carrier on which the second laser element is mounted. The carrier may be mounted on the mounting surface. In this case, the distance between the second emission port and the mounting surface varies depending on the thickness of the carrier. Therefore, the distance between the second emission port and the mounting surface can be changed only by changing the thickness of the carrier, so that the adjustment of the distance between the second emission port and the mounting surface can be facilitated.

The first emission port may be closer to a position where the first laser light and the second laser light overlap each other than the second emission port is. The second emission port may be provided at a position closer to the first laser element than a center of the carrier in a direction in which the first laser element and the second laser element are arranged is. In this case, since the second emission port is close to the first emission port, the angle between the emission direction of the first laser light and the emission direction of the second laser light can be made small. This makes it possible to suppress the degree of divergence of the first laser light and the second laser light downstream in the emission direction from the position where the first laser light and the second laser light overlap.

The above-described laser module may further include a metal body joining the second laser element and the carrier. The metal body may include a metal ball having rigidity. In this case, since the metal ball has rigidity, the distance between the second emission port and the carrier is defined by the metal ball. This makes it possible to easily adjust the distance between the second emission port and the carrier.

The second laser element may be disposed such that an emission direction of the second laser light is inclined with respect to the mounting surface. Since the distance from the mounting surface to the first emission port is different from the distance from the mounting surface to the second emission port, by inclining the emission direction of the second laser light with respect to the mounting surface, the portion where the first laser light and the second laser light overlap can be widened.

A beam divergence angle of the first laser element may be larger than a beam divergence angle of the second laser element. The first emission port may be closer to a position where the first laser light and the second laser light overlap each other than the second emission port is. In this case, the first laser light diverges more easily than the second laser light. Therefore, by bringing the first emission port closer to the position where the first laser light and the second laser light overlap each other than the second emission port, the degree of divergence of the laser light at the above-described position can be suppressed.

The above-described laser module may further include an extraction member provided with a through-hole through which a portion where the first laser light and the second laser light overlap each other passes. In this case, the portions of the first laser light and the second laser light which are not contained in the portion where the first laser light and the second laser light overlap each other are blocked. This makes it possible to remove stray light.

The above-described laser module may further include: a first photodetector that monitors a light intensity of the first laser light; and a second photodetector that monitors a light intensity of the second laser light. Each of the first laser element and the second laser element may be an edge-emitting laser element. The first photodetector may be disposed on a side opposite to an emission direction of the first laser light with respect to the first laser element. The second photodetector may be disposed on a side opposite to an emission direction of the second laser light with respect to the second laser element. In this case, since each of the first laser element and the second laser element is an edge-emitting laser element, each laser element emits laser light from both the front and rear end surfaces. The ratio between the light intensity of the laser light emitted from the front end surface and the light intensity of the laser light emitted from the rear end surface is set in advance. Therefore, the light intensity of the laser light can be monitored without using any optical component for branching the laser light. As a result, the laser module can be further miniaturized.

The above-described laser module may further include a third laser element having a third emission port that emits third laser light. The first laser light may be red light, the second laser light may be green light, and the third laser light may be blue light. In this case, a full-color laser module can be realized.

According to each aspect and each embodiment of the present disclosure, the laser module can be miniaturized.

### BRIEF DESCRIPTION OF THE DRAWINGS

FIG. 1 is a diagram schematically showing a configuration of a laser module according to an embodiment.

FIG. 2 is a diagram showing a relationship between an overlapping portion of laser light and a pinhole.

FIG. 3 is a perspective view of the light source unit and the pinhole plate shown in FIG. 1.

FIG. 4 is a plan view of the light source unit shown in FIG. 3.

FIG. 5 is a front view of the light source unit shown in FIG. 3.

FIG. 6 is a diagram for explaining a method of manufacturing the light source unit shown in FIG. 3.

FIG. 7 is a diagram for explaining a method of manufacturing the light source unit shown in FIG. 3.

FIG. 8 is a diagram for explaining a method of manufacturing the light source unit shown in FIG. 3.

FIG. 9 is a diagram for explaining a method of manufacturing the light source unit shown in FIG. 3.

FIG. 10 is a diagram showing an example of joining between a laser element and a carrier.

### DETAILED DESCRIPTION

Hereinafter, embodiments of the present disclosure will be described in detail with reference to the drawings. In the description of the drawings, the same elements are denoted by the same reference numerals, and redundant description will be omitted. In each figure, an XYZ coordinate system may be shown. The Y-axis direction is a direction intersecting (for example, orthogonal to) the X-axis direction and the Z-axis direction. The Z-axis direction is a direction intersecting (for example, orthogonal to) the X-axis direction and the Y-axis direction. For example, the X-axis direction is the front-rear direction, the Y-axis direction is the left-right direction, and the Z-axis direction is the up-down direction.

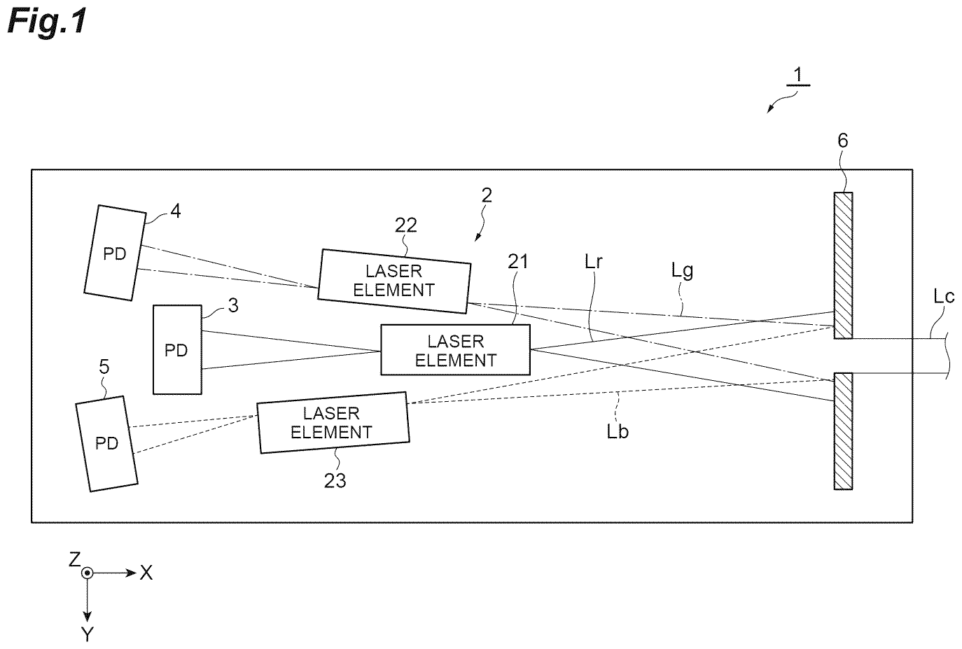

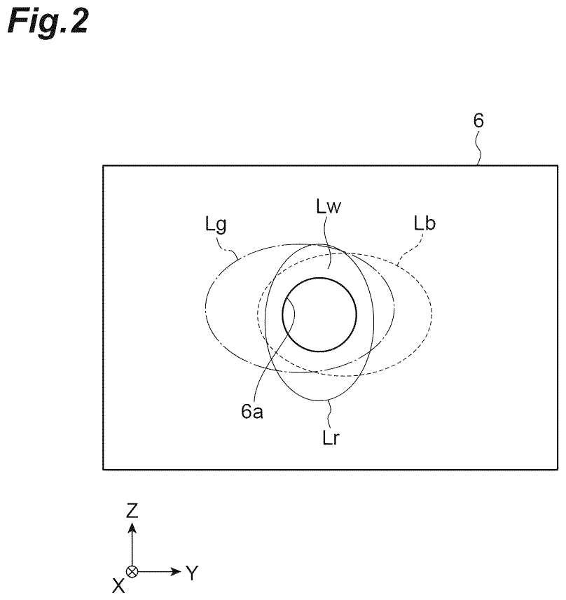

A laser module according to an embodiment will be described with reference to FIGS. 1 and 2. FIG. 1 is a diagram schematically showing a configuration of a laser module according to an embodiment. FIG. 2 is a diagram showing a relationship between an overlapping portion of laser light and a pinhole.

A laser module 1 shown in FIG. 1 is a module for emitting laser light Lc. The laser module 1 is applied to, for example, a retinal projection device mounted on a near-eye wearable device. Examples of the near-eye wearable device include smart glasses such as augmented reality (AR) glasses, virtual reality (VR) glasses, and mixed reality (MR) glasses. The laser module 1 includes a light source unit 2, a photodetector 3 (first photodetector), a photodetector 4 (second photodetector), a photodetector 5, and a pinhole plate 6 (extraction member).

The light source unit 2 includes a laser element 21 (first laser element), a laser element 22 (second laser element), and a laser element 23 (third laser element). Each of the laser element 21, the laser element 22, and the laser element 23 is a bare chip. Each of the laser element 21, the laser element 22, and the laser element 23 is, for example, an edge-emitting laser element, and emits laser light from both front and rear end surfaces. In each laser element, the ratio between the light intensity of the laser light emitted from the front end surface and the light intensity of the laser light emitted from the rear end surface is set in advance.

The laser element 21 emits red light Lr (first laser light), which is laser light having a red wavelength, from the front end surface. The laser element 22 emits green light Lg (second laser light), which is laser light having a green wavelength, from the front end surface. The laser element 23 emits blue light Lb (third laser light), which is laser light having a blue wavelength, from the front end surface. The laser element 21, the laser element 22, and the laser element 23 are arranged such that the red light Lr, the green light Lg, and the blue light Lb overlap each other. Details of the light source unit 2 will be described later.

The photodetector 3 is an element for monitoring the light intensity of the red light Lr. The photodetector 3 is provided on a side opposite to the emission direction of the red light Lr of the laser element 21. In other words, the photodetector 3 faces the rear end surface of the laser element 21. The photodetector 3 detects the light intensity of the laser light emitted from the rear end surface of the laser element 21.

The photodetector 4 is an element for monitoring the light intensity of the green light Lg. The photodetector 4 is provided on a side opposite to the emission direction of the green light Lg of the laser element 22. In other words, the photodetector 4 faces the rear end surface of the laser element 22. The photodetector 4 detects the light intensity of the laser light emitted from the rear end surface of the laser element 22.

The photodetector 5 is an element for monitoring the light intensity of the blue light Lb. The photodetector 5 is provided on a side opposite to the emission direction of the blue light Lb of the laser element 23. In other words, the photodetector 5 faces the rear end surface of the laser element 23. The photodetector 5 detects the light intensity of the laser light emitted from the rear end surface of the laser element 23.

The pinhole plate 6 is an optical component for extracting a portion Lw where the red light Lr, the green light Lg, and the blue light Lb overlap each other. The pinhole plate 6 has a plate-like shape. A pinhole 6a (through hole) passing through the pinhole plate 6 is provided in the pinhole plate 6. The laser light Lc is obtained by the portion Lw passing through the pinhole 6a. As shown in FIG. 2, the portion Lw is larger than the pinhole 6a.

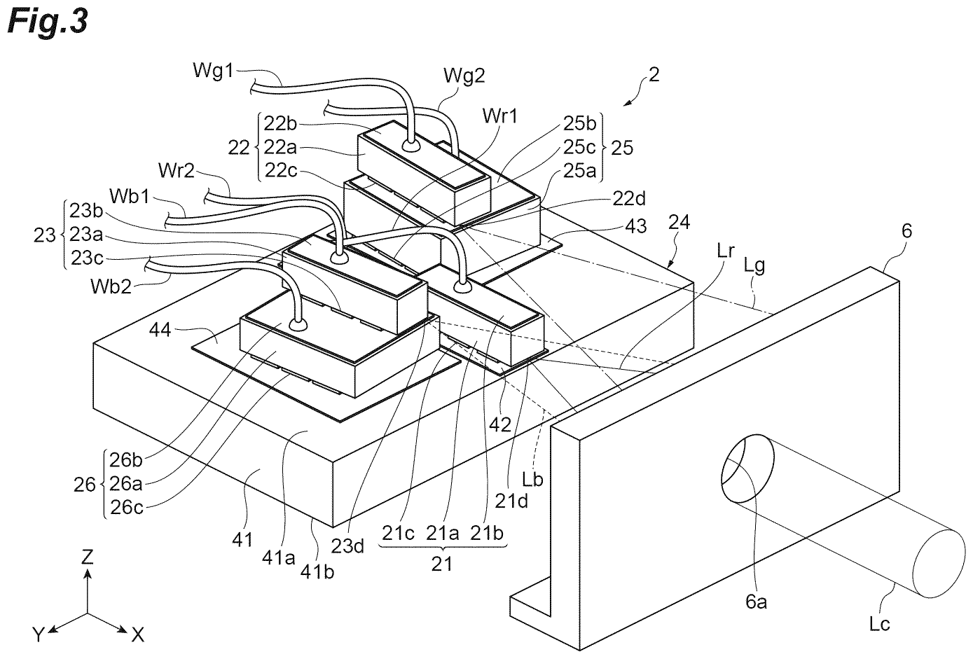

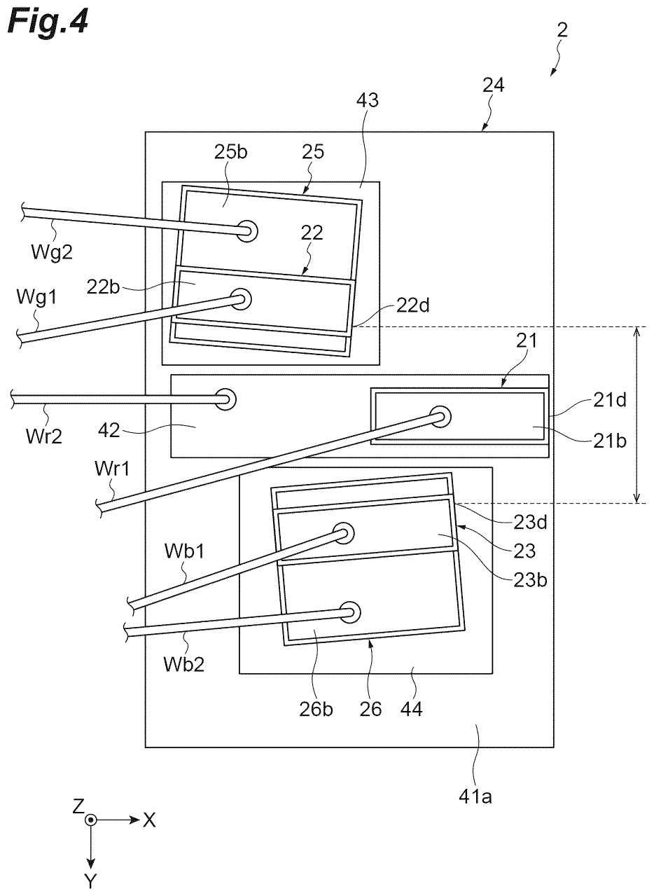

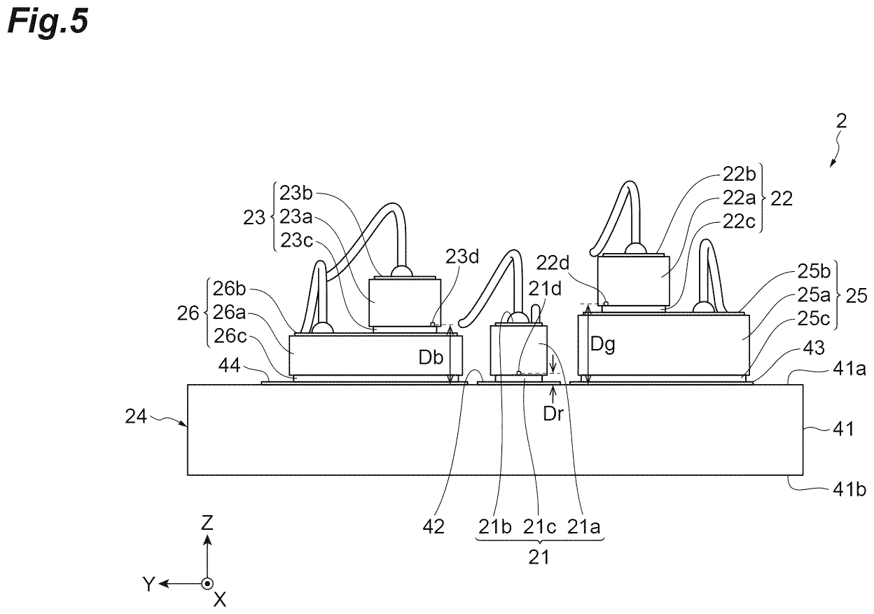

Next, the light source unit 2 will be described in detail with reference to FIGS. 3 to 5. FIG. 3 is a perspective view of the light source unit and the pinhole plate shown in FIG. 1. FIG. 4 is a plan view of the light source unit shown in FIG. 3. FIG. 5 is a front view of the light source unit shown in FIG. 3. In the laser module 1, the direction in which the pinhole plate 6 is positioned relative to the light source unit 2 is referred to as “forward” or “front”, and the direction in which the laser elements 21 to 23 are positioned relative to a substrate 24 described later is referred to as “upward” or “upper”. These directions determine “back (backward)”, “down (downward)”, “left” and “right”.

As shown in FIGS. 3 to 5, the laser element 21 includes a laser body 21a, an electrode 21b, and a metal layer 21c. The laser body 21a has a rectangular parallelepiped shape extending in the front-rear direction. The laser body 21a has an emission port 21d (first emission port) for emitting the red light Lr. The emission port 21d is provided on the front end surface of the laser element 21. The emission port 21d is located near the center in the left-right direction of the laser body 21a and near the lower end of the laser body 21a.

The electrode 21b is provided on the upper surface of the laser body 21a. The electrode 21b covers the upper surface of the laser body 21a. The electrode 21b is an upper electrode of the laser element 21. An example of the constituent material of the electrode 21b is a gold-tin alloy (AuSn). In the present embodiment, the electrode 21b functions as a cathode. The metal layer 21c is provided on the lower surface of the laser body 21a. The metal layer 21c covers the lower surface of the laser body 21a. The metal layer 21c is a solder layer for mounting the laser element 21. An example of the constituent material of the metal layer 21c is SAC (SnAgCu).

The laser element 22 includes a laser body 22a, an electrode 22b, and a metal layer 22c. The laser body 22a has a rectangular parallelepiped shape extending in the front-rear direction. The laser body 22a has an emission port 22d (second emission port) for emitting the green light Lg. The emission port 22d is provided on the front end surface of the laser element 22. The emission port 22d is located near the right end in the left-right direction of the laser body 22a and near the lower end of the laser body 22a.

The electrode 22b is provided on the upper surface of the laser body 22a. The electrode 22b covers the upper surface of the laser body 22a. The electrode 22b is an upper electrode of the laser element 22. An example of the constituent material of the electrode 22b is a gold-tin alloy (AuSn). In the present embodiment, the electrode 22b functions as a cathode. The metal layer 22c is provided on the lower surface of the laser body 22a. The metal layer 22c covers the lower surface of the laser body 22a. The metal layer 22c is a solder layer for mounting the laser element 22. An example of the constituent material of the metal layer 22c is SAC (SnAgCu).

The laser element 23 includes a laser body 23a, an electrode 23b, and a metal layer 23c. The laser body 23a has a rectangular parallelepiped shape extending in the front-rear direction. The laser body 23a has an emission port 23d (third emission port) for emitting the blue light Lb. The emission port 23d is provided on the front end surface of the laser element 23. The emission port 23d is located near the left end in the left-right direction of the laser body 23a and near the lower end of the laser body 23a.

The electrode 23b is provided on the upper surface of the laser body 23a. The electrode 23b covers the upper surface of the laser body 23a. The electrode 23b is an upper electrode of the laser element 23. An example of the constituent material of the electrode 23b is a gold-tin alloy (AuSn). In the present embodiment, the electrode 23b functions as a cathode. The metal layer 23c is provided on the lower surface of the laser body 23a. The metal layer 23c covers the lower surface of the laser body 23a. The metal layer 23c is a solder layer for mounting the laser element 23. An example of the constituent material of the metal layer 23c is SAC (SnAgCu).

The light source unit 2 further includes the substrate 24, a carrier 25, and a carrier 26. The substrate 24 is a pedestal on which the laser element 21 is mounted. In the present embodiment, not only the laser element 21 but also the laser element 22 and the laser element 23 are mounted on the substrate 24. The substrate 24 functions as a carrier of the laser element 21. The substrate 24 includes a base material 41, a pad 42, a pad 43, and a pad 44.

The base material 41 is a member having a rectangular plate-like shape. Examples of constituent materials of the base material 41 include silicon and aluminum nitride. The base material 41 has a mounting surface 41 a and a back surface 41b. The mounting surface 41a is a surface on which the laser element 21 is mounted. The back surface 41b is a surface opposite to the mounting surface 41a in the thickness direction (up-down direction) of the base material 41.

The pad 42, the pad 43, and the pad 44 are provided on the mounting surface 41a. The pad 42 is a plate-like metal member for mounting the laser element 21. An example of the constituent material of the pad 42 is a gold-tin alloy (AuSn). The outer shape of the pad 42 is larger than the outer shape of the laser element 21 in a plan view. In the present embodiment, the pad 42 has a rectangular plate-like shape extending in the front-rear direction. The pad 42 is provided near the center in the left-right direction of the mounting surface 41a, and extends from the front end of the base material 41 to the vicinity of the rear end thereof. The pad 42 also functions as a lower electrode of the laser element 21. In the present embodiment, the pad 42 functions as an anode.

The pad 43 is a plate-like metal member for mounting the laser element 22. In the present embodiment, the carrier 25 on which the laser element 22 is mounted is mounted on the pad 43. An example of the constituent material of the pad 43 is gold (Au). The outer shape of the pad 43 is larger than the outer shape of the carrier 25 in a plan view. In the present embodiment, the pad 43 has a rectangular plate-like shape. The pad 43 is provided on the left side of the pad 42 and extends from the vicinity of the center of the base material 41 in the front-rear direction to the vicinity of the rear end thereof.

The pad 44 is a plate-like metal member for mounting the laser element 23. In the present embodiment, the carrier 26 on which the laser element 23 is mounted is mounted on the pad 44. An example of the constituent material of the pad 44 is gold (Au). The outer shape of the pad 44 is larger than the outer shape of the carrier 26 in a plan view. In the present embodiment, the pad 44 has a rectangular plate-like shape. The pad 44 is provided on the right side of the pad 42 and extends from a position behind the front end of the base material 41 to a position in front of the rear end thereof.

The carrier 25 is a pedestal on which the laser element 22 is mounted. The carrier 25 is mounted on the mounting surface 41a. Specifically, the carrier 25 is mounted on the pad 43. The carrier 25 includes a base material 25a, a pad 25b, and a metal layer 25c. The base material 25a is a member having a rectangular plate-like shape. Examples of constituent materials of the base material 25a include silicon and aluminum nitride. The outer shape of the base material 25a (carrier 25) is larger than the outer shape of the laser element 22 in a plan view.

The pad 25b is provided on the upper surface of the base material 25a. The pad 25b covers the upper surface of the base material 25a. The pad 25b is a plate-like metal member for mounting the laser element 22. An example of the constituent material of the pad 25b is a gold-tin alloy (AuSn). The pad 25b also functions as a lower electrode of the laser element 22. In the present embodiment, the pad 25b functions as an anode.

The metal layer 25c is provided on the lower surface of the base material 25a. The metal layer 25c covers the lower surface of the base material 25a. The metal layer 25c is a solder layer for mounting the carrier 25. An example of the constituent material of the metal layer 25c is SAC (SnAgCu).

The carrier 26 is a pedestal on which the laser element 23 is mounted. The carrier 26 is mounted on the mounting surface 41a. Specifically, the carrier 26 is mounted on the pad 44. The carrier 26 includes a base material 26a, a pad 26b, and a metal layer 26c. The base material 26a is a member having a rectangular plate-like shape. Examples of constituent materials of the base material 26a include silicon and aluminum nitride. The outer shape of the base material 26a (carrier 26) is larger than the outer shape of the laser element 23 in a plan view.

The pad 26b is provided on the upper surface of the base material 26a. The pad 26b covers the upper surface of the base material 26a. The pad 26b is a plate-like metal member for mounting the laser element 23. An example of the constituent material of the pad 26b is a gold-tin alloy (AuSn). The pad 26b also functions as a lower electrode of the laser element 23. In the present embodiment, the pad 26b functions as an anode.

The metal layer 26c is provided on the lower surface of the base material 26a. The metal layer 26c covers the lower surface of the base material 26a. The metal layer 26c is a solder layer for mounting the carrier 26. An example of the constituent material of the metal layer 26c is SAC (SnAgCu).

The light source unit 2 further includes a wire Wr1, a wire Wr2, a wire Wg1, a wire Wg2, a wire Wb1, and a wire Wb2. The wire Wr1 and the wire Wr2 are members for supplying a drive current to the laser element 21. One end of the wire Wr1 is connected to the electrode 21b. One end of the wire Wr2 is connected to the pad 42.

The wire Wg1 and the wire Wg2 are members for supplying a drive current to the laser element 22. One end of the wire Wg1 is connected to the electrode 22b. One end of the wire Wg2 is connected to the pad 25b. The wire Wb1 and the wire Wb2 are members for supplying a drive current to the laser element 23. One end of the wire Wb1 is connected to the electrode 23b. One end of the wire Wb2 is connected to the pad 26b.

Next, the arrangement of the laser element 21, the laser element 22, and the laser element 23 will be described in detail with reference to FIGS. 3 to 5. In the present embodiment, the laser element 21, the laser element 22, and the laser element 23 have different radiation characteristics (horizontal beam divergence angle θh and vertical beam divergence angle θv). The laser element 21 has a beam divergence angle θh of 10° and a beam divergence angle θv of 32° under the condition that the light intensity is 5 mW, for example. The laser element 22 has a beam divergence angle θh of 7° and a beam divergence angle θv of 22° under the condition that the light intensity is 7 mW, for example. The laser element 23 has a beam divergence angle θh of 8° and a beam divergence angle θv of 23° under the condition that the light intensity is 7 mW, for example.

The beam divergence angle θh of the laser element 21 is larger than any of the beam divergence angle θh of the laser element 22 and the beam divergence angle θh of the laser element 23. The beam divergence angle θv of the laser element 21 is larger than any of the beam divergence angle θv of the laser element 22 and the beam divergence angle θv of the laser element 23. The larger the beam divergence angle of a laser element is, the more easily the laser light emitted from the laser element diverges. Therefore, the laser element 21 is disposed such that the distance between the emission port 21d and the pinhole 6a is shortest.

Specifically, the laser element 21 is disposed further forward than any of the laser element 22 and the laser element 23. In other words, the emission port 21d is closer to a position where the red light Lr, the green light Lg, and the blue light Lb overlap each other (pinhole 6a) than any of the emission port 22d and the emission port 23d is. The length of the substrate 24 (base material 41) in the up-down direction is set such that the emission port 21d is substantially at the same height as the center of the pinhole 6a. In the following description, the length in the up-down direction may be referred to as “thickness”. The laser element 21 is arranged substantially in parallel with the mounting surface 41a, and emits the red light Lr in parallel with the mounting surface 41a. Therefore, the emission port 21d is located in front of the pinhole 6a, and the central axis of the red light Lr (the emission direction of the red light Lr) coincides with the central axis of the pinhole 6a.

The beam divergence angle θh of the laser element 23 is slightly larger than the beam divergence angle θh of the laser element 22. The beam divergence angle θv of the laser element 23 is slightly larger than the beam divergence angle θv of the laser element 22. Therefore, the laser element 23 is disposed so that the distance between the emission port 23d and the pinhole 6a is shorter than the distance between the emission port 22d and the pinhole 6a.

Specifically, the laser element 23 is disposed further back than the laser element 21 and further forward than the laser element 22. In other words, the emission port 23d is closer to a position (pinhole 6a) where the red light Lr, the green light Lg, and the blue light Lb overlap each other than the emission port 22d is. The laser element 23 is mounted on the mounting surface 41a via the carrier 26. Therefore, the emission port 23d is located above the emission port 21d by the thickness of the carrier 26. In other words, the distance Db from the mounting surface 41a to the emission port 23d is larger than the distance Dr from the mounting surface 41a to the emission port 21d.

The laser element 23 is disposed on the right side of the laser element 21. The laser element 23 is provided on the carrier 26 at a position closer to the laser element 21 than the center in the left-right direction of the carrier 26 is. The emission port 23d is located near the left end of the laser body 23a. In other words, the emission port 23d is provided at a position closer to the laser element 21 than the center in the left-right direction of the carrier 26 is.

The direction of the laser element 23 (emission port 23d) is set so that the blue light Lb emitted from the emission port 23d passes through the pinhole 6a. Specifically, in the left-right direction, the laser element 23 is inclined so that the front end surface of the laser element 23 is closer to the laser element 21 than the rear end surface of the laser element 23 is. Therefore, the central axis of the blue light Lb (emission direction of the blue light Lb) is inclined so as to approach the central axis of the red light Lr as the central axis of the blue light Lb approaches the pinhole 6a.

In the example shown in FIG. 3, the laser element 23 is arranged substantially in parallel with the mounting surface 41a, and emits the blue light Lb in parallel with the mounting surface 41a. The laser element 23 may be inclined in the up-down direction so that the front end surface of the laser element 23 is closer to the mounting surface 41a than the rear end surface of the laser element 23 is.

The laser element 22 is disposed further back than any of the laser element 21 and the laser element 23. In other words, the emission port 22d is farther away from the position (pinhole 6a) where the red light Lr, the green light Lg, and the blue light Lb overlap each other than any of the emission port 21d and the emission port 23d is. The laser element 22 is mounted on the mounting surface 41a via the carrier 25. Therefore, the emission port 22d is located above the emission port 21d by the thickness of the carrier 25. Since the thickness of the carrier 25 is thicker than the thickness of the carrier 26, the emission port 22d is located above the emission port 23d. In other words, the distance Dg from the mounting surface 41a to the emission port 22d is larger than any of the distance Dr and the distance Db.

The laser element 22 is disposed on the left side of the laser element 21. The laser element 22 is provided on the carrier 25 at a position closer to the laser element 21 than the center in the left-right direction of the carrier 25 is. The emission port 22d is located near the right end of the laser body 22a. In other words, the emission port 22d is provided at a position closer to the laser element 21 than the center in the left-right direction of the carrier 25 is.

The direction of the laser element 22 (emission port 22d) is set so that the green light Lg emitted from the emission port 22d passes through the pinhole 6a. Specifically, in the left-right direction, the laser element 22 is inclined so that the front end surface of the laser element 22 is closer to the laser element 21 than the rear end surface of the laser element 22 is. Therefore, the central axis of the green light Lg (emission direction of the green light Lg) is inclined so as to approach the central axis of the red light Lr as the central axis of the green light Lg approaches the pinhole 6a.

In the example shown in FIG. 3, the laser element 22 is arranged substantially in parallel with the mounting surface 41a, and emits the green light Lg in parallel with the mounting surface 41a. The laser element 22 may be inclined in the up-down direction so that the front end surface of the laser element 22 is closer to the mounting surface 41a than the rear end surface of the laser element 22 is.

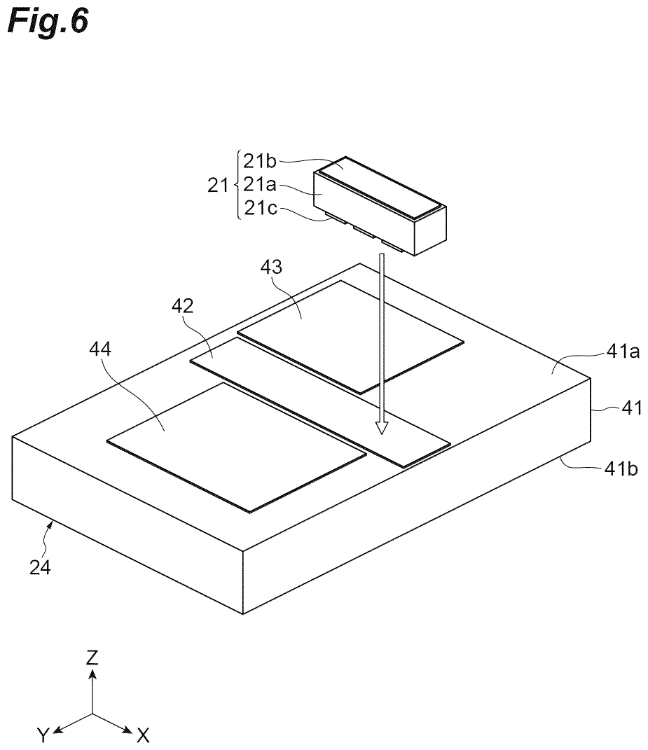

Next, a method of manufacturing the light source unit 2 will be described with reference to FIGS. 6 to 9. FIGS. 6 to 9 are diagrams for explaining a method of manufacturing the light source unit shown in FIG. 3.

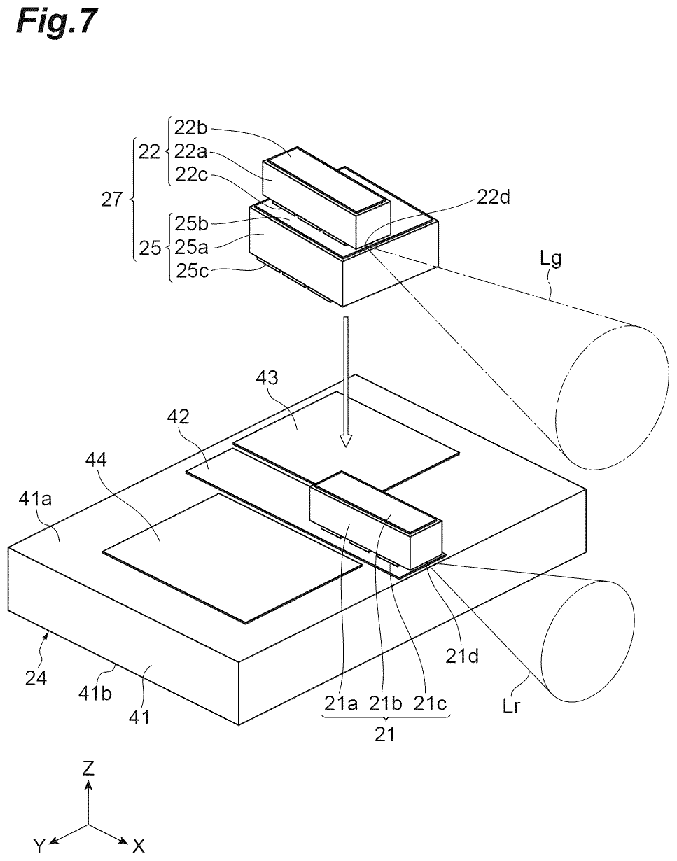

First, the laser elements 21 to 23, the substrate 24, and the carriers 25 and 26 are prepared. Then, by mounting the laser element 22 on the carrier 25, the laser element 22 and the carrier 25 are unitized to form a unit 27 (see FIG. 7). Specifically, the laser element 22 is placed on the carrier 25 such that the metal layer 22c is in contact with the pad 25b. Then, the metal layer 22c is melted by heating the metal layer 22c, and then the metal layer 22c is solidified, whereby the laser element 22 is joined to the carrier 25.

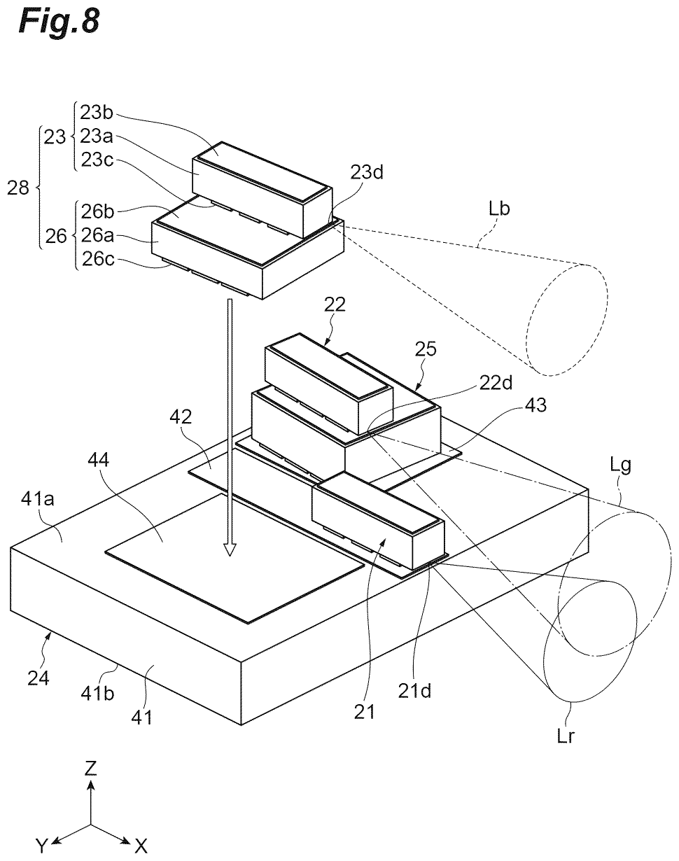

Similarly, by mounting the laser element 23 on the carrier 26, the laser element 23 and the carrier 26 are unitized to form a unit 28 (see FIG. 8). Specifically, the laser element 23 is placed on the carrier 26 such that the metal layer 23c is in contact with the pad 26b. Then, the metal layer 23c is melted by heating the metal layer 23c, and then the metal layer 23c is solidified, whereby the laser element 23 is joined to the carrier 26.

Subsequently, as shown in FIG. 6, the laser element 21 is mounted on the substrate 24. Specifically, the laser element 21 is placed on the substrate 24 such that the metal layer 21c is in contact with the pad 42. Then, the metal layer 21c is melted by heating the metal layer 21c, and then the metal layer 21c is solidified, whereby the laser element 21 is joined to the substrate 24.

Subsequently, as shown in FIG. 7, the laser element 22 is mounted on the substrate 24. Specifically, the unit 27 is placed on the substrate 24 such that the metal layer 25c is in contact with the pad 43. At this time, the unit 27 is placed in a state where the laser element 21 is emitting the red light Lr and the laser element 22 is emitting the green light Lg. By active alignment, the direction and inclination of the unit 27 are adjusted so that the red light Lr and the green light Lg overlap each other. Then, the metal layer 25c is melted by heating the metal layer 25c, and then the metal layer 25c is solidified, whereby the unit 27 is joined to the substrate 24.

Subsequently, as shown in FIG. 8, the laser element 23 is mounted on the substrate 24. Specifically, the unit 28 is placed on the substrate 24 such that the metal layer 26c is in contact with the pad 44. At this time, the unit 28 is placed in a state where the laser element 21 is emitting the red light Lr, the laser element 22 is emitting the green light Lg, and the laser element 23 is emitting the blue light Lb. By active alignment, the direction and inclination of the unit 28 are adjusted so that the red light Lr, the green light Lg, and the blue light Lb overlap each other. Then, the metal layer 26c is melted by heating the metal layer 26c, and then the metal layer 26c is solidified, whereby the unit 28 is joined to the substrate 24.

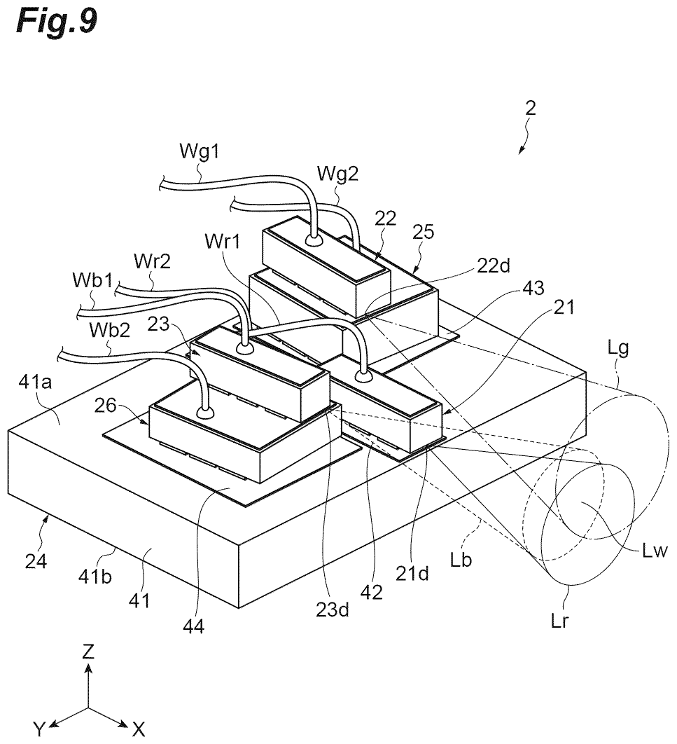

Subsequently, as shown in FIG. 9, wire bonding is performed. Specifically, one end of the wire Wr1 is connected to the electrode 21b, and one end of the wire Wr2 is connected to the pad 42. Similarly, one end of the wire Wg1 is connected to the electrode 22b, and one end of the wire Wg2 is connected to the pad 25b. Similarly, one end of the wire Wb1 is connected to the electrode 23b, and one end of the wire Wb2 is connected to the pad 26b.

As described above, the light source unit 2 is manufactured. The laser element 23 may be mounted on the substrate 24 before the laser element 22. Among the laser elements 21 to 23, the laser element 21, which is positioned the most forward, is mounted first, and the laser element 22 and the laser element 23 are mounted so that the green light Lg and the blue light Lb are superposed on the red light Lr. That is, the directions and inclinations of the laser element 22 and the laser element 23 are adjusted so that the red light Lr, the green light Lg, and the blue light Lb overlap each other with reference to the red light Lr emitted along the central axis of the pinhole 6a. Since the laser element 22 and the laser element 23 are disposed further back than the laser element 21, the possibility that the reference laser light (here, red light Lr) is blocked by other laser elements or the like is reduced. Therefore, the mounting efficiency of the laser element 22 and the laser element 23 can be improved.

In the laser module 1 described above, the laser element 21, the laser element 22, and the laser element 23 are arranged such that the red light Lr, the green light Lg, and the blue light Lb overlap each other. This makes it possible to multiplex the red light Lr, the green light Lg, and the blue light Lb without using any optical component such as a dichroic mirror. As a result, the full-color laser module 1 can be realized, and the laser module 1 can be miniaturized.

Since the laser element 21, laser element 22, and laser element 23 are arranged three dimensionally, the distance Dr, the distance Dg, and the distance Db are different from each other. Specifically, the distance Db is larger than the distance Dr, and the distance Dg is larger than the distance Db. Therefore, even if the emission port 22d is located near the emission port 21d, the possibility that the green light Lg is blocked by the laser element 21 is reduced. Therefore, the emission port 22d can be made closer to the emission port 21d as compared with the case where the distance Dr and the distance Dg are the same. Similarly, even if the emission port 23d is located near the emission port 21d, the possibility that the blue light Lb is blocked by the laser element 21 is reduced. Therefore, the emission port 23d can be made closer to the emission port 21d as compared with the case where the distance Dr and the distance Db are the same.

As described above, the emission direction of the red light Lr, the emission direction of the green light Lg, and the emission direction of the blue light Lb can be made close to each other. In other words, the angle between any two emission directions among the emission direction of the red light Lr, the emission direction of the green light Lg, and the emission direction of the blue light Lb can be made small. This makes it possible to suppress the degree of divergence of the red light Lr, the green light Lg, and the blue light Lb downstream in the emission direction from the position where the red light Lr, the green light Lg, and the blue light Lb overlap each other.

The laser element 22 is mounted on the carrier 25, and the laser element 23 is mounted on the carrier 26. The carrier 25 and the carrier 26 are mounted on the mounting surface 41a. Therefore, the distance Dg varies depending on the thickness of the carrier 25, and the distance Db varies depending on the thickness of the carrier 26. That is, the distance Dg can be changed only by changing the thickness of the carrier 25, and the distance Db can be changed only by changing the thickness of the carrier 26. Therefore, the adjustment of the distance Dg and the distance Db can be facilitated.

Since the distance Dr, the distance Dg, and the distance Db are different from each other, when the red light Lr, the green light Lg, and the blue light Lb are emitted in parallel with the mounting surface 41a, the portion Lw may be narrowed. On the other hand, when the laser element 22 is disposed such that the emission direction of the green light Lg is inclined with respect to the mounting surface 41a, the portion where the red light Lr and the green light Lg overlap each other can be widened, so that the portion Lw can be widened. Similarly, when the laser element 23 is disposed such that the emission direction of the blue light Lb is inclined with respect to the mounting surface 41a, the portion where the red light Lr and the blue light Lb overlap each other can be widened, and the portion Lw can be widened.

The beam divergence angle θh of the laser element 21 is larger than any of the beam divergence angle θh of the laser element 22 and the beam divergence angle θh of the laser element 23. The beam divergence angle θv of the laser element 21 is larger than any of the beam divergence angle θv of the laser element 22 and the beam divergence angle θv of the laser element 23. The larger the beam divergence angle of a laser element is, the more easily the laser light emitted from the laser element diverges. Therefore, since the red light Lr diverges more easily than any of the green light Lg and the blue light Lb, the emission port 21d is brought closer to the position (pinhole 6a) where the red light Lr, the green light Lg, and the blue light Lb overlap each other than any of the emission port 22d and the emission port 23d is, so that the degree of divergence of the laser light as a whole at the above-described position can be suppressed.

The emission port 22d is provided at a position closer to the laser element 21 than the center in the left-right direction of the carrier 25 is. Therefore, since the emission port 22d is close to the emission port 21d, the angle between the emission direction of the red light Lr and the emission direction of the green light Lg can be made small. Similarly, the emission port 23d is provided at a position closer to the laser element 21 than the center in the left-right direction of the carrier 26 is. Therefore, since the emission port 23d is close to the emission port 21d, the angle between the emission direction of the red light Lr and the emission direction of the blue light Lb can be made small. As described above, it is possible to suppress the degree of divergence of the red light Lr, the green light Lg, and the blue light Lb downstream in the emission direction from the position where the red light Lr, the green light Lg, and the blue light Lb overlap each other.

The laser light Lc is obtained by the portion Lw passing through the pinhole 6a, and the portions of the red light Lr, the green light Lg, and the blue light Lb which are not contained in the portion Lw are blocked by the pinhole plate 6. This makes it possible to remove stray light.

Since each of the laser elements 21 to 23 is an edge-emitting laser element, each laser element emits laser light from both the front and rear end surfaces. The photodetector 3 is disposed on the side opposite to the emission direction of the red light Lr with respect to the laser element 21, and receives the laser light emitted from the rear end surface of the laser element 21. In the laser element 21, the ratio between the light intensity of the red light Lr emitted from the front end surface and the light intensity of the laser light emitted from the rear end surface is set in advance. Therefore, the light intensity of the red light Lr can be monitored without using any optical component for branching the red light Lr.

Similarly, the photodetector 4 is disposed on the side opposite to the emission direction of the green light Lg with respect to the laser element 22, and receives the laser light emitted from the rear end surface of the laser element 22. In the laser element 22, the ratio between the light intensity of the green light Lg emitted from the front end surface and the light intensity of the laser light emitted from the rear end surface is set in advance. Therefore, the light intensity of the green light Lg can be monitored without using any optical component for branching the green light Lg.

Similarly, the photodetector 5 is disposed on the side opposite to the emission direction of the blue light Lb with respect to the laser element 23, and receives the laser light emitted from the rear end surface of the laser element 23. In the laser element 23, the ratio between the light intensity of the blue light Lb emitted from the front end surface and the light intensity of the laser light emitted from the rear end surface is set in advance. Therefore, the light intensity of the blue light Lb can be monitored without using any optical component for branching the blue light Lb. As described above, the laser module 1 can be further miniaturized.

The laser module according to the present disclosure is not limited to the above-described embodiments.

For example, the laser module 1 is not limited to a configuration which multiplexes the red light Lr, the green light Lg, and the blue light Lb, but may be configured to multiplex at least two laser lights. In this case, a laser element for emitting each laser light is disposed so that at least two laser lights overlap each other.

The light source unit 2 may further include a carrier on which the laser element 21 is mounted. The carrier may be mounted on the mounting surface 41a. The light source unit 2 does not have to include at least one of the carrier 25 and the carrier 26. The emission port 21d, the emission port 22d, and the emission port 23d may be located on the same plane parallel to the mounting surface 41a. That is, the distance Dr, the distance Dg, and the distance Db may be equal to each other.

The carrier 25 does not have to be mounted on the mounting surface 41a. The carrier 26 does not have to be mounted on the mounting surface 41a. That is, the laser element 21, the laser element 22, and the laser element 23 does not have to be provided on the same substrate 24, but may be provided on individual carriers.

Instead of the emission port 21d, the emission port 22d may be located in front of the pinhole 6a, and the central axis of the green light Lg (emission direction of the green light Lg) may coincide with the central axis of the pinhole 6a. In this case, the laser element 21, the laser element 22, and the laser element 23 may be arranged in the left-right direction in that order. Alternatively, the emission port 23d may be located in front of the pinhole 6a, and the central axis of the blue light Lb (emission direction of the blue light Lb) may coincide with the central axis of the pinhole 6a. In this case, the laser element 21, the laser element 23, and the laser element 22 may be arranged in the left-right direction in that order.

The laser module 1 may further include a collimating lens for converting the laser light Lc into parallel light.

The laser element 21 may be disposed such that the emission direction of the red light Lr is inclined with respect to the mounting surface 41a. The laser element 22 may be disposed such that the emission direction of the green light Lg is inclined with respect to the mounting surface 41a. The laser element 23 may be disposed such that the emission direction of the blue light Lb is inclined with respect to the mounting surface 41a.

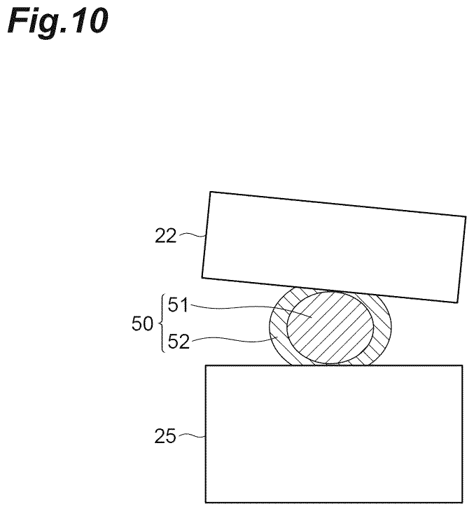

As shown in FIG. 10, laser module 1 may further include a metal body 50. In the example shown in FIG. 10, the metal body 50 is used for joining the laser element 22 and the carrier 25 (pad 25b). The metal body 50 includes a metal ball 51 and a plating layer 52. The metal ball 51 has rigidity. An example of the constituent material of the metal ball 51 is copper. The plating layer 52 is provided on the surface of the metal ball 51. The plating layer 52 covers the entire surface of the metal ball 51. The plating layer 52 is melted by heating the metal body 50, and then the plating layer 52 is solidified, whereby the laser element 22 is joined to the carrier 25 via the metal body 50.

The metal body 50 may be gold to gold interconnect (GGI). In this case, the metal body 50 includes a rigid metal ball 51. An example of the constituent material of the metal ball 51 is gold (Au). The metal body 50 performs joined by friction caused by ultrasonic vibration.

Since the metal ball 51 has rigidity, the metal ball 51 is not easily deformed. Therefore, the inclination and the distance Dg of the laser element 22 are defined by the metal ball 51. This makes it possible to easily adjust the inclination and the distance Dg of the laser element 22. Instead of adjusting the inclination by the metal body 50, the carrier 25 itself may be inclined.

The metal body 50 may be used for joining the laser element 21 and the mounting surface 41a (pad 42), or may be used for joining the laser element 23 and the carrier 26 (pad 26b). The metal body 50 may be used for joining the carrier 25 and the mounting surface 41a (pad 43), or may be used for joining the carrier 26 and the mounting surface 41a (pad 44).

### Additional Statements

### Clause 1

A laser module comprising:
a first laser element having a first emission port that emits first laser light; and
a second laser element having a second emission port that emits second laser light,
wherein the first laser element and the second laser element are disposed such that the first laser light and the second laser light overlap each other.

### Clause 2

The laser module according to clause 1, further comprising a substrate having a mounting surface on which the first laser element is mounted,
wherein a distance from the mounting surface to the first emission port is different from a distance from the mounting surface to the second emission port.

### Clause 3

The laser module according to clause 2, further comprising a carrier on which the second laser element is mounted,
wherein the carrier is mounted on the mounting surface.

### Clause 4

The laser module according to clause 3,
wherein the first emission port is closer to a position where the first laser light and the second laser light overlap each other than the second emission port is, and
wherein the second emission port is provided at a position closer to the first laser element than a center of the carrier in a direction in which the first laser element and the second laser element are arranged is.

### Clause 5

The laser module according to clause 3 or 4, further comprising a metal body joining the second laser element and the carrier,
wherein the metal body comprises a metal ball having rigidity.

### Clause 6

The laser module according to any one of clauses 2 to 5,
wherein the second laser element is disposed such that an emission direction of the second laser light is inclined with respect to the mounting surface.

### Clause 7

The laser module according to any one of clauses 1 to 6,
wherein a beam divergence angle of the first laser element is larger than a beam divergence angle of the second laser element, and
wherein the first emission port is closer to a position where the first laser light and the second laser light overlap each other than the second emission port is.

### Clause 8

The laser module according to any one of clauses 1 to 7, further comprising an extraction member provided with a through-hole through which a portion where the first laser light and the second laser light overlap each other passes.

### Clause 9

The laser module according to any one of clauses 1 to 8, further comprising:
a first photodetector configured to monitor a light intensity of the first laser light; and
a second photodetector configured to monitor a light intensity of the second laser light,
wherein each of the first laser element and the second laser element is an edge-emitting laser element,
wherein the first photodetector is disposed on a side opposite to an emission direction of the first laser light with respect to the first laser element, and
wherein the second photodetector is disposed on a side opposite to an emission direction of the second laser light with respect to the second laser element.

### Clause 10

The laser module according to any one of clauses 1 to 9, further comprising a third laser element having a third emission port that emits third laser light,
wherein the first laser light is red light, the second laser light is green light, and the third laser light is blue light.

What is claimed is:

1. A laser module comprising:
a first laser element having a first emission port that emits first laser light; and
a second laser element having a second emission port that emits second laser light,
wherein the first laser element and the second laser element are disposed such that the first laser light and the second laser light overlap each other.

2. The laser module according to claim 1, further comprising a substrate having a mounting surface on which the first laser element is mounted,
wherein a distance from the mounting surface to the first emission port is different from a distance from the mounting surface to the second emission port.

3. The laser module according to claim 2, further comprising a carrier on which the second laser element is mounted,
wherein the carrier is mounted on the mounting surface.

4. The laser module according to claim 3,
wherein the first emission port is closer to a position where the first laser light and the second laser light overlap each other than the second emission port is, and
wherein the second emission port is provided at a position closer to the first laser element than a center of the carrier in a direction in which the first laser element and the second laser element are arranged is.

5. The laser module according to claim 3, further comprising a metal body joining the second laser element and the carrier,
wherein the metal body comprises a metal ball having rigidity.

6. The laser module according to claim 2,
wherein the second laser element is disposed such that an emission direction of the second laser light is inclined with respect to the mounting surface.

7. The laser module according to claim 1,
wherein a beam divergence angle of the first laser element is larger than a beam divergence angle of the second laser element, and
wherein the first emission port is closer to a position where the first laser light and the second laser light overlap each other than the second emission port is.

8. The laser module according to claim 1, further comprising an extraction member provided with a through-hole through which a portion where the first laser light and the second laser light overlap each other passes.

9. The laser module according to claim 1, further comprising:
a first photodetector configured to monitor a light intensity of the first laser light; and
a second photodetector configured to monitor a light intensity of the second laser light,
wherein each of the first laser element and the second laser element is an edge-emitting laser element,
wherein the first photodetector is disposed on a side opposite to an emission direction of the first laser light with respect to the first laser element, and
wherein the second photodetector is disposed on a side opposite to an emission direction of the second laser light with respect to the second laser element.

10. The laser module according to claim 1, further comprising a third laser element having a third emission port that emits third laser light,
wherein the first laser light is red light, the second laser light is green light, and the third laser light is blue light.
